(19) United States
(12) Patent Application Publication
(10) Pub. No.: US 2005/0067712 A1
(43) Pub. Date: Mar. 31, 2005

(54) Semiconductor apparatus and method of fabricating the same

(76) Inventors: Toshikazu Imaoka, Ogaki-City (JP); Ryosuke Usui, Ichinomiya-City (JP); Atsushi Nakano, Isesaki-City (JP); Atsushi Kato, Kiryu-City (JP)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 10/951,214

(22) Filed: Sep. 27, 2004

(30) Foreign Application Priority Data
Sep. 29, 2003 (JP) 2003-338619
Sep. 10, 2004 (JP) 2004-264134

(51) Int. Cl. H01L 23/48

(52) U.S. Cl. 257/774; 257/779; 257/784

(57) ABSTRACT

A semiconductor apparatus includes a first conductive film and a second conductive film provided on respective sides of an insulating resin film. A circuit element is mounted on the second conductive film. The circuit element is electrically connected to the second conductive film. The second conductive film is provided to cover a via plug. The via plug is tapered with a progressively smaller diameter toward the second conductive film and away from the first conductive film.

### BACKGROUND OF THE INVENTION

1. Field of the Invention

The present invention relates to a semiconductor apparatus in which a plug is formed and a method of fabricating the same.

2. Description of the Related Art

With portable electronic appliances such as portable telephones, PDAs, DVCs and DSCs becoming more and more advanced in their capabilities, miniaturization and weight reduction of products have become essential for market acceptance. Accordingly, highly-integrated system LSIs for achieving these goals are demanded. Since ease and convenience of use are required of these electronic appliances, high capabilities and high performance are essential requirements for LSIs used in these appliances. While the number of I/Os is increasing as a result of increasingly high integration of LSI chips, there is also a persistent requirement for miniaturization of packages themselves. In order to meet the requirements for high integration and miniaturization, development of a semiconductor package adapted for high-density packaging of semiconductor components on a substrate is called for. A packaging technology called chip size packaging (CSP) has been developed in a variety of forms to address these requirements.

For example, a patent document No. 1 describes CSP. FIG. 8 shows a configuration of a via plug according to the related art. A patent document No. 2 also described a via with a configuration as shown in FIG. 8.

Referring to FIG. 8, a first conductive film 2 and a second conductive film 4 are formed on respective sides of an insulating resin film 6. A circuit element 20 is mounted on the second conductive film 4 via a paste 18. The circuit element 20 is electrically connected to the second conductive film 4 by a bonding wire 22. The first conductive film 2 and the second conductive film 4 are patterned to have a predetermined configuration, a photo solder resist 14 being embedded in the pattern. The first conductive film 2 and the second conductive film 4 are electrically connected to each other via a via plug 10. The first conductive film 2 is electrically connected to a bump 16.

Thus, the via plug 10 according to the related art is formed in a via hole that opens to the surface on which the circuit element 20 is mounted. Therefore, the via plug 10 is tapered to have a progressively smaller diameter downward and away from the surface on which the circuit element 20 is mounted.

Related Art List

[Patent document No. 1] Japanese Laid-Open Patent Application No. 2002-94247 (paragraph 0046, FIGS. 1, 11 etc.)

[Patent document No. 2] Japanese Laid-Open Patent Application No. 2002-110717

By configuring the surface on which the circuit element 20 is mounted to have an opening, it is difficult to maintain the mounting surface of the circuit element 20 to be flat. When the via plug 10 is formed beneath an area in which the circuit element 20 is provided, an empty hole 24 as shown in FIG. 8 is created. This produces an unfavorable result in a heating process that follows the packaging, resulting in a less reliable semiconductor apparatus.

The problem described above has usually inhibited provision of the via plug 10 beneath an area in which the circuit element 20 is provided. Therefore, a limit has been imposed on heat dissipation of a circuit element.

Further, by providing the via plug 10 to open to the surface on which the circuit element 20 is mounted, the bonding wire 22 can only be provided at limited locations on the mounting surface of the circuit element 20. Consequently, the length of the bonding wire 22 is extended. This presents a problem in that improvement in the high-frequency characteristic of the semiconductor apparatus is difficult.

### SUMMARY OF THE INVENTION

The present invention has been done in view of the above-mentioned circumstances and its object is to provide a technology in which heat dissipation characteristic and high-frequency characteristic of a semiconductor apparatus are improved.

The present invention provides a semiconductor apparatus comprising: a first conductive film; an insulating resin film provided on the first conductive film; a plug provided on the first conductive film and the insulating resin film; a second conductive film provided on the insulating resin film and formed to cover the plug; and an element provided on the second conductive film.

The term “element” refers to a circuit element such as a semiconductor element or a passive element. A plug may be a via plug or a contact plug. By providing the second conductive film on the insulating resin film and the plug, it is ensured that the surface on which the element is provided is flat. The top surface of the insulating film and the top surface of the plug may be formed to be substantially flush with each other. With this, the plug may be formed beneath an area in which the element is placed so that heat dissipation of the semiconductor apparatus is improved.

The present invention also provides a semiconductor apparatus comprising: a first conductive film; an insulating resin film provided on the first conductive film; a second conductive film provided on the insulating resin film; an element provided on the second conductive film; and a plug provided on the insulating resin film, wherein the plug has a tapered side wall with a progressively smaller diameter toward the second conductive film and away from the first conductive film.

By configuring the plug to have a tapered side wall with a progressively smaller diameter toward the surface on which the element is provided, it is ensured that a plug area occupying the surface on which the element is provided is smaller than that of the related-art plug having a tapered side wall with a progressively larger diameter toward the surface on which the element is provided. A wiring pattern should be formed above the plug for electrical connection with the element. For dispersion of thermal stress, a safe distance must be provided between the end of the wiring pattern and the end of the plug. By ensuring that the plug occupies a comparatively smaller area in the surface on which the element is provided, the apparatus can be designed such that an area in an upper wiring layer necessary for each plug is smaller than in the related art. Accordingly, the semiconductor apparatus is miniaturized. By reducing an area necessary for each plug, the apparatus can be designed such that a shorter bonding wire connects the element and the second conductive film. With this, parasitic inductance is reduced and high-frequency performance is improved.

In the semiconductor apparatus according to the invention, the element may be formed above an area in which the plug is formed.

According to the invention, the second conductive film is placed on the plug so that the area on which the element is provided is flat. Accordingly, the element may be formed above an area in which the plug is formed. By providing the element above an area in which the plug is formed, a large number of plugs may be provided. This results in proper heat dissipation of the semiconductor apparatus.

In the semiconductor apparatus of the present invention, a point of contact with a wire bonding may be provided at an arbitrary location on the second conductive film. Since the length of wiring is reduced according to this arrangement, the miniaturization of the semiconductor apparatus is facilitated. Further, owing to a resultant reduction in parasitic inductance, adverse effects occurring in high frequencies are suppressed, and ease of design and operation performance are enhanced. The point of contact with the wire bonding may be connected to another point of contact provided on the semiconductor element or the second conductive film. Since a portion of the semiconductor apparatus of the invention immediately above the plug is flat, arbitrary locations on the second conductive film naturally include the portion immediately above the plug.

In the semiconductor apparatus according to the present invention, portions of the first conductive film and the plug may be used as lead electrodes. With this, the semiconductor apparatus may be mounted on a motherboard without using a core structure. Therefore, the length wiring path is reduced. As the length of wiring path is reduced, the length of heat dissipation path is reduced so that heat dissipation of the semiconductor apparatus is improved. As a result, the operating temperature of the circuit element is lowered so that the performance and reliability of the semiconductor apparatus are improved. Further, owing to a resultant reduction in parasitic inductance, adverse effects occurring in high frequencies are suppressed so that the ease of design and performance of the semiconductor apparatus are improved.

In the semiconductor apparatus of the present invention, an insulating or conductive material may fill a space formed by the plug. By filling the space formed by the plug by a conductive material, an area of cross section of the conductive body perpendicular to the direction of conduction of heat generated by the semiconductor element is increased. Accordingly, heat resistance is lowered and heat dissipation is improved. As a result, the operating temperature of the semiconductor element is lowered so that the performance and reliability of the semiconductor apparatus are improved. Further, owing to a resultant reduction in parasitic inductance, adverse effects occurring in high frequencies are suppressed so that the ease of design and operation performance of the semiconductor apparatus are improved. The insulating material may be a photo solder resist or a transfer mold resin. The conductive material may be a metal such as copper and tin. Tin may be included in solder. The space formed by the plug may not be filled by the filling material.

By filling the space formed by the plug by a conductive material or an insulating material, the mechanical strength of the substrate is enhanced. An additional benefit is that intrusion of water is prevented even when a crack occurs in the interior wall of the plug (plated conductive layer). As a result, the reliability of the apparatus is improved.

In the semiconductor apparatus of the present invention, the space formed by the plug may be filled and a projected conductive electrode projected outward beyond the first conductive film may be provided. By filling the space formed by the plug by the projected electrode without using a conductive material, the favorable effects derived from filling the space formed by the plug by the conductive material are obtained at a low cost.

In the semiconductor apparatus of the present invention, the plug may be formed by laser irradiation in a direction facing the first conductive film, using the second conductive film as a stopper. In the related-art structure where the plug is formed to open to the surface on which the element is formed, a relatively large width of wiring pattern must be secured for canceling misalignment of laser irradiation for forming the via hole. When the via hole is formed by laser irradiation directed to the surface opposite to the surface on which the element is formed as in the semiconductor apparatus of the present invention, a relatively small width of wiring pattern is necessary to cancel misalignment. Therefore, the semiconductor apparatus may be designed such that an area required in an upper wiring layer for each plug is reduced in comparison with the related art so that miniaturization of the apparatus is facilitated. By reducing an area required for each plug, the apparatus may be designed such that the wiring connecting the element with the second conductive film is comparatively short. With this, parasitic inductance is reduced so that the high-frequency performance is improved.

In the semiconductor apparatus of the present invention, a plurality of plugs may be provided. In this case, an insulating material or a conductive material may fill a space formed by at least one plug. A projected conductive electrode which fills a space formed by at least one plug and which is projected outward beyond the first conductive film may be provided.

The present invention provides a method of fabricating a semiconductor apparatus comprising the steps of: forming a plug by irradiating a structure including a first conductive film and a second conductive film sandwiching an insulating resin film in a direction facing the first conductive film, using the second conductive film as a stopper layer; and placing an element on the second conductive film.

In accordance with the above method, the semiconductor apparatus with the above-described structure is obtained. The resultant high-frequency performance of the semiconductor apparatus is excellent. Heat dissipation of the semiconductor apparatus is also favorable. Further, miniaturization of the semiconductor apparatus is facilitated. According to the method of the present invention, the semiconductor apparatus with these features are fabricated at a low cost.

The method of fabricating a semiconductor apparatus according to the present invention may further comprise the step of filling a space formed by the plug by an insulating or conductive material. By filling the space formed by the plug by the conductive material, the operation performance and reliability of semiconductor apparatus are improved. By filling the space formed by the plug by a conductive material or an insulating material, the mechanical strength of the substrate is enhanced. An additional benefit is that intrusion of water is prevented even when a crack occurs in the interior plug wall (plated, conductive layer). As a result, the reliability of the apparatus is improved.

The method of fabricating a semiconductor apparatus according to the present invention may further comprise a step of providing a projected conductive electrode which fills a space formed by the plug and which is projected outward beyond the first conductive film. By filling the space formed by the plug by the projected electrode without using a conductive material, the favorable effects derived from filling the space formed by the plug by the conductive material are obtained at a low cost.

Described above is an explanation of the structure according to the present invention. Optional combinations of constituting elements may also be practiced as additional modes of the present invention. Implementations of the invention in other categories may also be practiced as additional modes of the present invention.

According to the present invention, heat dissipation and high-frequency characteristics of a semiconductor apparatus are improved.

### BRIEF DESCRIPTION OF THE DRAWINGS

FIG. 1 is a section showing a structure of the semiconductor apparatus according to an embodiment of the present invention.

FIGS. 2A-2E are sections showing a process of fabricating a semiconductor apparatus according to the embodiment.

FIG. 3 is a section showing a variation of the semiconductor apparatus shown in FIG. 1.

FIG. 4 is a section showing another variation of the semiconductor apparatus shown in FIG. 1.

FIGS. 5A and 5B are sections showing a configuration of a via plug according to the present invention and a configuration of a via plug according to the related art, respectively.

FIG. 6 is a section showing a variation of the semiconductor apparatus shown in FIG. 1.

FIG. 7 is a section showing a structure of the semiconductor apparatus fabricated according to an example.

FIG. 8 is a section showing a structure of a semiconductor apparatus according to the related art.

### DETAILED DESCRIPTION OF THE INVENTION

The invention will now be described by reference to the preferred embodiments. This doe's not intend to limit the scope of the present invention, but to exemplify the invention.

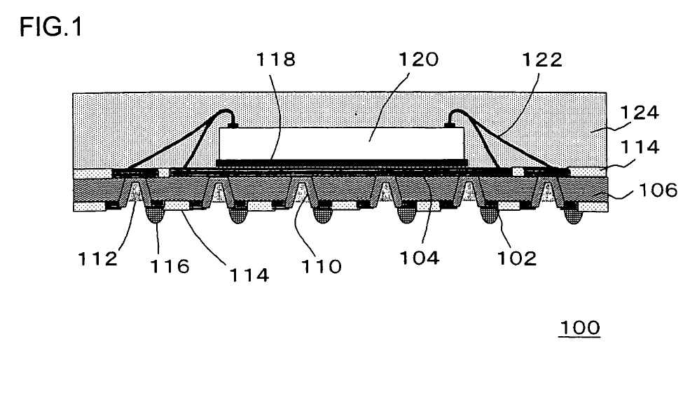

FIG. 1 is a section showing a structure of a semiconductor apparatus according to an embodiment of the present invention.

In this embodiment, the semiconductor apparatus 100 comprises: a first conductive film 102, an insulating resin film 106 formed on the first conductive film 102, a second conductive film 104 formed on the insulating resin film 106, a circuit element 120 mounted on the second conductive film 104, a sealing resin 124 for sealing the circuit element 120, a bonding wire 122 electrically connecting the circuit element 120 with the second conductive film 104, a via plug 110 electrically connecting the first conductive film 102 with the second conductive film 104, and a bump 116 electrically connected to the via plug 110. The circuit element 120 is fixed on the second conductive film 104 by a conductive paste 118 formed of, for example, silver. The first conductive film 102 and the second conductive film 104 are patterned into a layout of a predetermined configuration. A photo solder resist 114 is embedded in the layout formed by patterning.

The circuit element 120 is a semiconductor element such as a transistor, diode and IC chip, or a passive element such as a chip capacitor and chip resistor.

A via hole opening to the first conductive film 102 is formed in the insulating resin film 106. The via plug 110 is formed in the via hole. The second conductive film 104 is formed on the top surface of the via plug 110. The via plug 110 does not open to the second conductive film 104. The second conductive film 104 is formed to cover the via plug 110. The top surface of the via plug 110 and top surface of the insulating resin film 106 are formed to be substantially flush with each other. With this, it is ensured that the second conductive film 104 is flat. Further, the via plug 110 has a tapered side wall with a progressively smaller diameter toward the second conductive film 104 and away from the first conductive film 102.

A filling material 112 is embedded in the via hole in which the via plug 110 is formed.

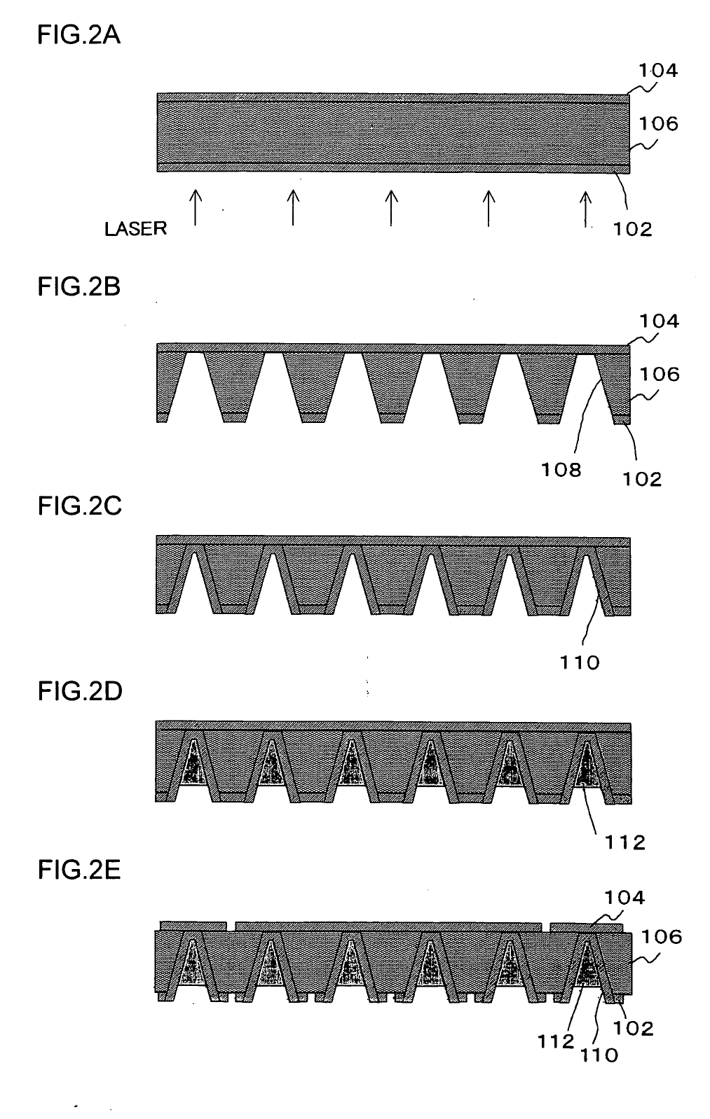

FIGS. 2A-2E are sections illustrating a process of fabricating the semiconductor apparatus shown in FIG. 1. A sheet, in which the first conductive film 102 and the second conductive film 104 are formed on the insulating resin film 106, is prepared. Subsequently, a resist for forming an opening for the via hole is applied on the first conductive film 102. Portions of the first conducting film 102 are selectively removed by wet etching, using the resist as a mask. With this, selected portions of the first conductive film 102, where the via hole is formed, are removed. Subsequently, the surface of the sheet on which the first conductive film 102 is formed is irradiated by a CO₂ gas laser (FIG. 2A). The second conductive film 104 functions as a stopper layer.

The CO₂ gas laser is emitted in a first condition and in a second condition in which the pulse width is modified. A laser with a pulse period of 0.25 ms and an output of 1.0 W is used. The first condition may be such that the pulse width is 8-10 μs and the number of shots is 1. The second condition may be such that the pulse width is 3-5 μs and the pulse interval is 25 ms or longer and the number of shots is 3. By irradiation, the via hole 108 having a tapered side wall with a progressively smaller diameter toward the second conductive film 104 and away from the first conductive film 102 is formed (FIG. 2B)

The first conductive film 102 and the second conductive film 104 may be formed of a rolled metal such as a rolled copper foil. For example, epoxy resin, melamine derivative such as BT resin, liquid crystal polymer, PPE resin, polyimide resin, fluororesin, phenol resin or polyamide bismaleimide may be used to form the insulating resin film 106.

Epoxy resin may be bisphenol A type resin, bisphenol F type resin, bisphenol S type resin, phenol novolac resin, creosol Novolak type epoxide resin, tris phenol methane type epoxide resin, alicycle epoxy resin, and the like.

Melamine derivative may be melamine, melamine cyanurate, methylol melamine, (iso) cyanuric acid, melam, melem, succino guamine, melamine sulfate, acetoguanamine sulfate, melam sulfate, guanyl melamine sulfate, melamine resin, BT resin, cyanuric acid, iso-cyanuric acid, iso-cyanuric acid derivatives, melamine isocyanurate, benzoguanamine, acetoguanamine, or guanidine compounds.

Aromatic system liquid crystalline polyester, polyimide, polyesteramide and resin composites containing these are examples of liquid crystal polymer. Liquid crystalline polyester or liquid crystalline polyester composites, characterized by excellent balance in heat resistance, workability and moisture absorption, is preferable.

Liquid crystalline polyester may be (1) a product of reaction between aromatic dicarboxylic acid, aromatic diol and aromatic hydroxy carboxylic acid, (2) a product of reaction between a combination of aromatic hydroxy carboxylic acids, (3) a product of reaction between aromatic dicarboxylic acid and aromatic diol, (4) a product of reaction between polyester such as polyethylene terephthalate and aromatic hydroxy carboxylic acid, or the like. In place of aromatic dicarboxylic acid, aromatic diol and aromatic hydroxy carboxylic acid, ester derivatives of these may be used. Aromatic dicarboxylic acid, aromatic diol and aromatic hydroxy carboxylic acid may have their aromatic part replaced by halogen atoms, alkyl groups or aryl groups.

Examples of a repeated structural unit are a repeated structural unit derived from aromatic dicarboxylic acid (formula (i) below), a repeated structural unit derived from aromatic diol (formula (ii) below), and a repeated structural unit derived from aromatic hydroxy carboxylic acid (formula (iii) below).
—CO-A₁—CO— (i)
(where A1 indicates a divalent ligand containing an aromatic ring)
—O-A₂—O— (ii)
(wherein A₂ indicates a divalent ligand containing an aromatic ring)
—CO-A₃-O— (iii)
(wherein A₃ indicates a divalent ligand containing an aromatic ring)

Preferably, a material to form the insulating film 106 is an aramid nonwoven fabric. With this, workability is improved. Para-aramid fiber or meta-aramid fiber may be used as aramid fiber. For example, poly (p-phenylene terephthalamide) (PPD-T) may be used to form the para-aramid fiber, and poly (m-phenylene isophthalamide) (MPD-I) may be used as meta-aramid.

After forming the via hole 108, the interior of the via hole 108 is roughened and cleaned by a wet process. Subsequently, a conductive material is embedded in the via hole 108 so as to form the via plug 110 (FIG. 2C). The via plug 110 may be formed by electroless plating or electroplating. The via plug 110 may be formed as described below. After forming a thin film of a thickness of about 0.5-1 μm on the entirety of the via hole 108 using electroless copper plating, a film of about 20 μm is formed by electroplating. Normally, palladium is used as a catalyst for electroless plating. In order to attach a catalyst for electroless plating to a flexible insulator substrate, palladium is contained in a water solution in the form of complex, the flexible insulating substrate is steeped in the solution so as to attach the palladium complex on the surface thereof, and the palladium complex is reduced to palladium as a metal, using a reducing agent. In this way, a core for plating is formed on the surface of the flexible insulating substrate.

Subsequently, the filling material 112 is embedded in a space formed by the via plug 110 (FIG. 2D). The filling material 112 may be an insulating material, a conductive material, etc. The insulating material may be a photo solder resist or a transfer mold resin. The conductive material may be solder containing tin. Alternatively, copper may be embedded as the filling material 112 by plating etc. In this embodiment, it is assumed that copper is embedded in a space formed by the via plug 110 by plating.

Subsequently, the layout is formed by patterning the first conductive film 102 and the second conductive film 104 to have a predetermined configuration (FIG. 2E). The layout is formed by, for example, removing unnecessary portions of the conductive film by spraying a chemical etchant where the film is free of the resist and is exposed, using a photoresist as a mask in etching. An etching resist material used in an ordinary printed circuit board may be used as an etching resist. In this case, the layout may be formed by silk screen printing using a resist ink. Alternatively, a laminate of a photosensitive dry film as an etching resist may be formed on the conductive film, a photomask transmitting light in a shape of a conductive layout may be placed on the laminate, the laminate is exposed to ultraviolet light, and those portions not exposed are removed by a developing solution. When a copper foil is used as the first conductive film 102 or the second conductive film 104, a chemical etchant used in an ordinary printed circuit board may be used. For example, a solution of cupric chloride and hydrochloric acid, a ferric chloride solution, a solution of sulfuric acid and hydrogen peroxide or an ammonium persulfate solution may be used.

Subsequently, the photo solder resist 114 (see FIG. 1) is embedded in the layout formed by the second conductive film 104.

For appropriate contact with the circuit element 120, the surface of the pattern thus formed on which the circuit element 120 is mounted may be roughened. Subsequently, the conductive paste 118 is formed in an area where the circuit element 120 is mounted. Subsequently, the circuit element 120 is mounted on the conductive paste 118. The circuit element 120 is fixed on the conductive paste 118 by a waxing material such as solder or by an adhesive. The circuit element 120 is connected to the second conductive film 104 via the bonding wire 122. Points of contact with the bonding wire 122 may be at arbitrary locations on the second conducting film 104. Since the portion immediately above the top of the via plug 110 is flat, the point of contact may be at the location of the second conducting film 104 immediately above the via plug 110. By providing the point of contact in the vicinity of an electrode of the circuit element 120, it is ensured that the bonding wire 122 is short. It is also possible to connect the point of contact on the second conducting film 104 away from the via plug 110 with another point of contact on the second conductive film 104 by the bonding wire 122.

Since the second conductive film 104 is formed to cover the via plug 110 in this embodiment, it is ensured that the surface on which the circuit element 120 is mounted is flat. With this, it is possible to mount the circuit element 120 above an area in which the via plug 110 is formed. Therefore, it is possible to form a large number of via plugs 110 in the semiconductor apparatus 100 so that the heat dissipation of the semiconductor apparatus 100 is improved.

Subsequently the circuit element 120 is sealed by the sealing resin 124. Sealing of the circuit element 120 may be performed using a die. Although only one circuit element 120 is illustrated, a larger number of circuit elements may be sealed simultaneously. The circuit element 120 may be sealed by the sealing resin 124 using transfer molding, injection molding, potting or dipping. A thermosetting resin such as epoxy resin may be used in transfer molding or potting. A thermoplastic resin such as polyimide resin and polyphenylene sulfide may be used in injection molding. Alternatively, a sealing resin film may be attached to the circuit element 120 for sealing.

Subsequently, the bump 116 for electrical connection with the first conductive film 102 is formed. This results in the semiconductor apparatus 100 with a structure shown in FIG. 1.

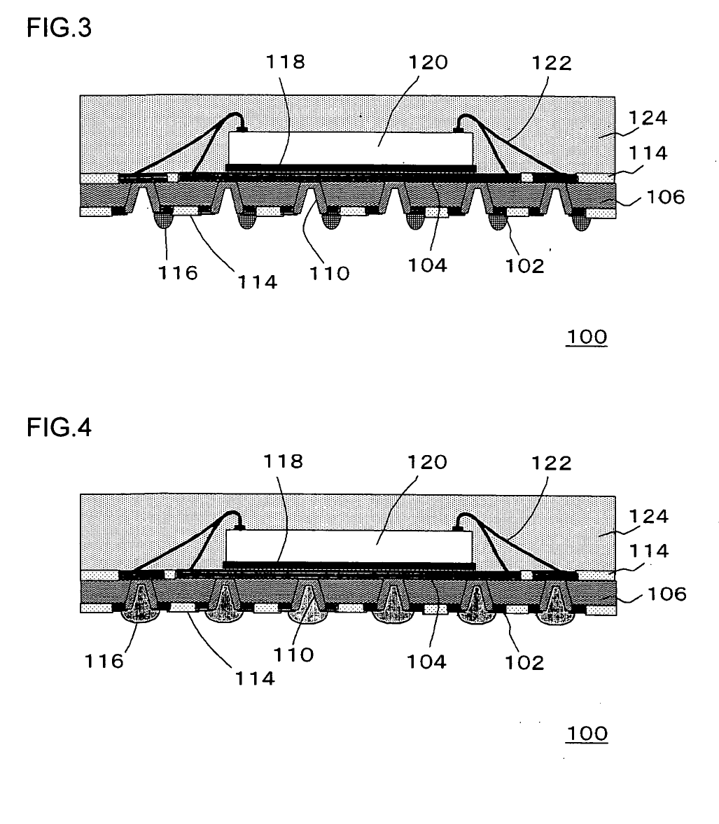

The description given above referring to FIGS. 1 and 2A-2E is directed to an embodiment in which the filling material 112 is embedded in the via hole 108. Alternatively, the via hole 108 may not be filled by the filling material 112. FIG. 3 shows a structure of the semiconductor apparatus 100 in which the via hole 108 is not filled by the filling material 112.

In the semiconductor apparatus 100 illustrated, portions of the first conductive film 102 and the via plug 110 are used as lead electrodes. With this, the semiconductor apparatus 100 may be mounted on a motherboard without using a core structure so that the length of wiring path is reduced. As the length of wiring path is reduced, the length of heat dissipation path is reduced so that the heat dissipation of the semiconductor apparatus 100 is improved. As a result, the operating temperature of the circuit element 120 is lowered so that the performance and reliability of the semiconductor apparatus 100 are improved. Further, owing to a resultant reduction in parasitic inductance, adverse effects occurring in high frequencies are suppressed so that the ease of design and performance of the semiconductor apparatus are improved.

As shown in FIG. 4, in the semiconductor apparatus 100 in which the via hole 108 is not filled by the filling material 112, the space formed by the via plug 110 may be filled by providing the conductive bump 116 projected beyond the first conductive film 102. In this way, the space formed by the via plug 110 is filled by the bump 116 without using a conductive material. Therefore, an area of cross section of the conductive body perpendicular to the direction of conduction of heat generated by the semiconductor element is increased. Accordingly, heat resistance is reduced and heat dissipation is improved. As a result, the operating temperature of the semiconductor element is lowered so that the performance and reliability of the semiconductor apparatus are improved. Further, owing to a resultant reduction in parasitic inductance, adverse effects occurring in high frequencies are suppressed so that the ease of design and performance of the semiconductor apparatus are improved.

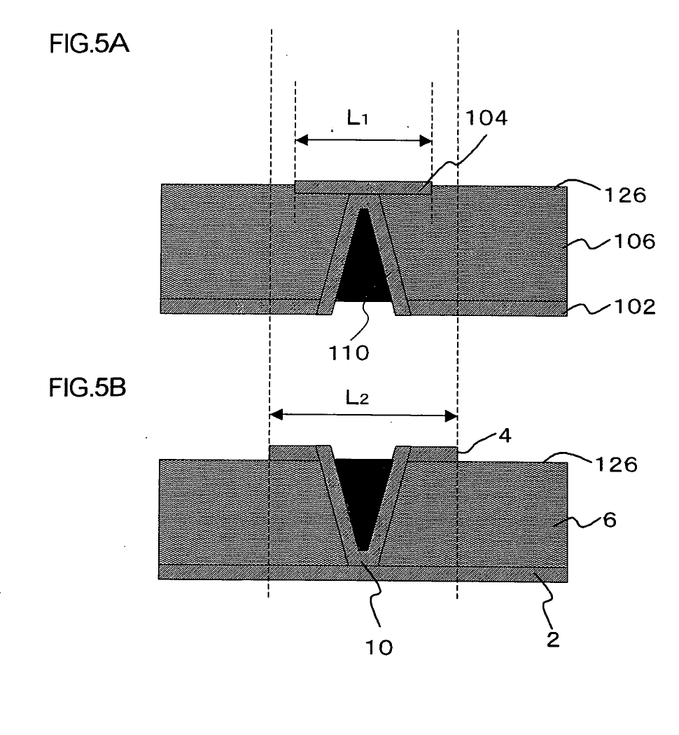

FIG. 5A shows a configuration of the via plug 110 according to this embodiment, and FIG. 5B shows a configuration of the via plug 10 according to the related art. FIG. 5A shows a structure of the via plug 110 according to this embodiment formed to open to the surface opposite to a mounting surface 126 on which the circuit element 120 is mounted. FIG. 5B shows a structure of the via plug 10 according to the related art formed to open to the mounting surface 126 on which the circuit element 120 is mounted.

In this embodiment, the via plug 110 has a tapered side wall with a progressively smaller diameter toward the second conductive film 104 and way from the first conductive film 102. Therefore, the width of the wiring pattern of the second conductive film 104 formed on the via plug 110 may be relatively narrower. More specifically, as shown in FIGS. 5A and 5B, a safe distance must be provided between the end of the wiring pattern and the end of the via plug 110 for appropriate heat dissipation. When the via hole that opens to the second conductive film 4 is formed as in the related art, the width of wiringmust be relatively large in consideration of misalignment that possibly occurs in laser irradiation. Accordingly, a width L₂ of the wiring pattern is necessary for each via plug 10 according to the related art. In contrast, the width of wiring pattern may be L₁ (L₂>L₁) for each via plug 110 in the semiconductor apparatus 100 according to this embodiment. Since an area required for each via plug 110 is reduced as described above, the size of the semiconductor apparatus 100 is reduced, given that the same number of via plugs are provided as in the related art.

Since the width of wiring pattern for each via plug 110 is reduced, the bonding wire 122 connecting the circuit element 120 with the second conductive film 104 may be comparatively short. With this, parasitic inductance is reduced so that the high-frequency performance is improved.

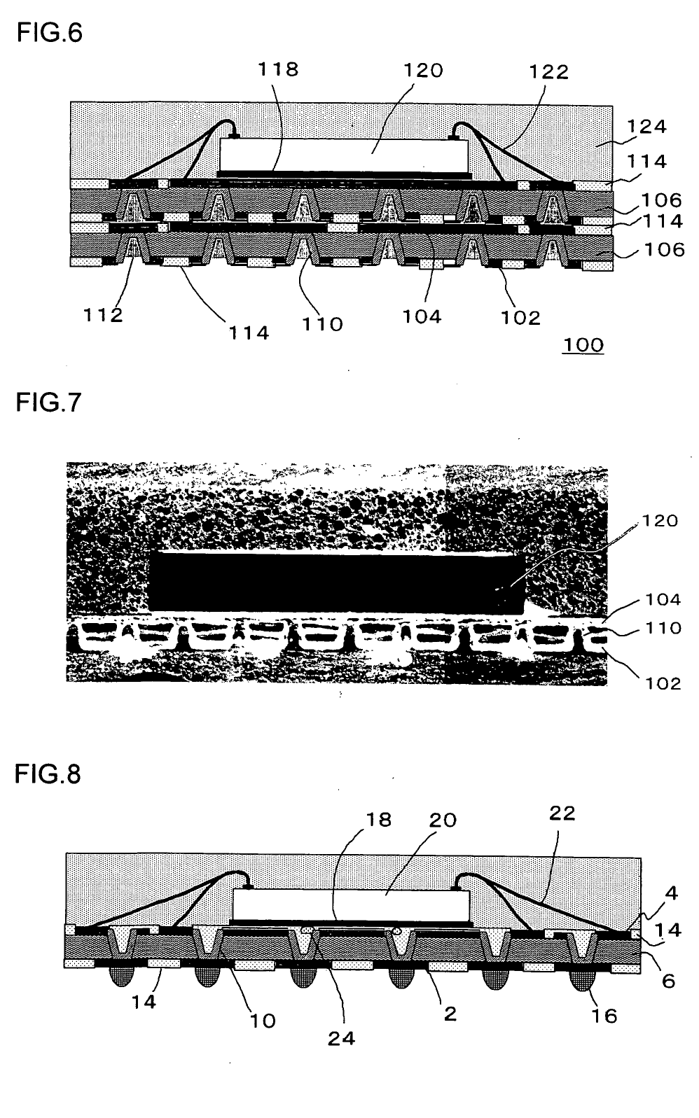

The semiconductor apparatus 100 according to the embodiment may be a stack of a plurality of layers as shown in FIG. 6.

The semiconductor apparatus described above may be applied to an integrated system in board (ISB)™ package. A description will now be given of an ISP package.

An ISB package is a coreless system in package, a type of electronic circuit packaging mainly comprising bare semiconductor chips, that has a copper wiring pattern but does not use a core (substrate) for supporting circuit components. Japanese Laid-Open Patent Application No. 2002-110717 describes a system in package of this type.

In the related art, an ISB package is produced by forming a stack of a plurality of layers of conductive patterns on a conductive foil that also functions as a supporting substrate, mounting circuit elements in a resultant multilayer structure, molding the structure by an insulating resin, and removing the conductive foil. The conductive foil may have its underside exposed.

According to this package, the following advantages are available.
(i) Since the package is coreless, small-sized and low-profile transistors, ICs and LSIs can be fabricated.
(ii) Since elements including transistors, system LSIs, and capacitors and resistors of a chip type can be built into the circuit for packaging, a highly advanced system in package (SIP) is realized.
(iii) By employing a combination of currently available semiconductor chips, a system LSI can be developed in a short period of time.
(iv) Since there is no core material underneath the bare semiconductor chips, resultant heat dissipation is favorable.
(v) Since the circuit wiring is made of copper and not supported by any core material, a low-dielectric circuit wiring, exhibiting excellent characteristics in high-speed data transfer and high-frequency circuits, results.
(vi) Since electrodes are embedded inside the package, particle contaminants derived from an electrode material are controlled.
(vii) The package size is free. Since the volume of discarded materials per one package is approximately 1/10 of a 64-pin SQFP package, the load placed on the environment is reduced.
(viii) A new system configuration, embodying a concept shift from a printed circuit board carrying components to a circuit board with built-in functions, is realized.
(ix) Designing an ISB pattern is as easy as pattern design of a printed circuit board so that engineers of a set manufacturer can design the pattern on their own.

The via plug 110 described in this embodiment may be formed in a multilayer wiring structure produced by building a stack of a plurality of layers of insulating resin films and conductive films so the advantages already described are available. As described, the combined advantages, i.e. the advantages from ISB and the advantages according to the via plug 110 of this embodiment, such as improvement in heat dissipation, reduction in parasitic inductance, miniaturization of semiconductor apparatus, are available.

### EXAMPLES

A sheet, similar to the one described by referring to FIGS. 2A-2E, in which the first conductive film 102 and the second conductive film 104, both of which are copper foils, are formed on the respective sides of the insulating resin film 106, was used. The surface on which the first conductive film 102 is formed was irradiated by CO₂ gas laser so as to create the via hole 108. The via plug 110 was formed inside the via hole 108. The CO₂ gas laser with a pulse period of 0.25 ms and an output of 1.0 W was used. The first condition was such that the pulse width is 8 μs and the number of shots is 1. The second condition was such that the pulse width is 3-5 μs and the pulse interval is 25 ms and the number of shots is 3.

FIG. 7 shows a section of a structure of the semiconductor apparatus 100 thus fabricated. As illustrated, it was confirmed that the via hole 110 according to this example has a tapered side wall with a progressively smaller diameter toward the second conductive film 104 (the surface on which the circuit element 120 is formed) and away from the first conductive film 102. The diameter of the via hole was 100 μmφ at the bottom and 80 μmφ at the top.

The via plug having a side wall of a similar configuration was formed when the CO₂ gas laser with a pulse period of 0.25 ms and an output of 1.0 W was used, the first condition being such that the pulse width is 10 μs and the number of shots is 1, and the second condition being such that the pulse width is 5 μs and the number of shots is 3.

Described above is an explanation based on the embodiment and the example. The embodiment and the example are only illustrative in nature and it will be obvious to those skilled in the art that variations are possible within the scope of the present invention.

The circuit element 120 may be a stack of a plurality of layers carrying elements such that a second element is placed on a first element. In this case, combinations of the first element and the second element include a combination of SRAM and Flash memory, a combination of SRAM and PRAM etc.

In the above-described embodiment, the via hole 108 is formed by using a CO₂ gas laser. Alternatively, machine work, chemical etching using chemicals, or dry etching using plasma may be used.

1. A semiconductor apparatus comprising:
a first conductive film;
an insulating resin film provided on said first conductive film;
a plug provided on said first conductive film and said insulating resin film;
a second conductive film provided on said insulating resin film and formed to cover said plug; and
an element provided on said second conductive film.

2. The semiconductor apparatus according to claim 1, wherein said plug has a tapered side wall with a progressively smaller diameter toward said second conductive film and away from said first conductive film.

3. A semiconductor apparatus comprising:
a first conductive film;
an insulating resin film provided on said first conductive film;
a second conductive film provided on said insulating resin film;
an element provided on said second conductive film; and
a plug provided on said insulating resin film, wherein
said plug has a tapered side wall with a progressively smaller diameter toward said second conductive film and away from said first conductive film.

4. The semiconductor apparatus according to claim 1, wherein said element is provided above an area in which said plug is formed.

5. The semiconductor apparatus according to claim 2, wherein said element is provided above an area in which said plug is formed.

6. The semiconductor apparatus according to claim 3, wherein said element is provided above an area in which said plug is formed.

7. The semiconductor apparatus according to claim 1, wherein a point of contact with a wire bonding is provided at an arbitrary location on said second conductive film.

8. The semiconductor apparatus according to claim 2, wherein a point of contact with a wire bonding is provided at an arbitrary location on said second conductive film.

9. The semiconductor apparatus according to claim 5, wherein a point of contact with a wire bonding is provided at an arbitrary location on said second conductive film.

10. The semiconductor apparatus according to claim 1, wherein portions of said first conductive film and said plug are used as lead electrodes.

11. The semiconductor apparatus according to claim 2, wherein portions of said first conductive film and said plug are used as lead electrodes.

12. The semiconductor apparatus according to claim 5, wherein portions of said first conductive film and said plug are used as lead electrodes.

13. The semiconductor apparatus according to claim 1, wherein an insulating material or a conductive material fills a space formed by said plug.

14. The semiconductor apparatus according to claim 2, wherein an insulating material or a conductive material fills a space formed by said plug.

15. The semiconductor apparatus according to claim 5, wherein an insulating material or a conductive material fills a space formed by said plug.

16. The semiconductor apparatus according to claim 11, wherein a projected conductive electrode which fills a space formed by said plug and which is projected outward beyond said first conductive film is provided.

17. The semiconductor apparatus according to claim 12, wherein a projected conductive electrode which fills a space formed by said plug and which is projected outward beyond said first conductive film is provided.

18. A method of fabricating a semiconductor apparatus comprising the steps of:
forming a plug by irradiating a structure including a first conductive film and a second conductive film sandwiching an insulating resin film in a direction facing the first conductive film, using the second conductive film as a stopper layer; and
placing an element on the second conductive film.

19. The semiconductor apparatus according to claim 18, further comprising the step of: filling a space formed by the plug with an insulating or conductive material.

20. The method of fabricating a semiconductor apparatus according to claim 19, further comprising the step of providing a projected conductive electrode which fills a space formed by said plug and which is projected outward beyond said first conductive film.
